(19) United States
(12) Patent Application Publication
(10) Pub. No.: US 2025/0259835 A1
(43) Pub. Date: Aug. 14, 2025

(54) METHOD OF INTEGRATED COPPER OXIDE REMOVAL AND LOW K REPAIR PROCESS

(71) Applicant: Applied Materials, Inc., Santa Clara, CA (US)

(72) Inventors: Xinyi LU, Santa Clara, CA (US); Kent Qiujing ZHAO, San Francisco, CA (US); Bo XIE, San Jose, CA (US); Chi-I LANG, Cupertino, CA (US); Chengen WANG, Cupertino, CA (US); Chidambara A. RAMALINGAM, Fremont, CA (US); Li-Qun XIA, Santa Clara, CA (US); Shankar VENKATARAMAN, San Jose, CA (US)

(21) Appl. No.: 18/783,581

(22) Filed: Jul. 25, 2024

Related U.S. Application Data
(60) Provisional application No. 63/552,472, filed on Feb. 12, 2024.

(51) Int. Cl. H01L 21/02; C07F 7/10; C23G 5/00

(52) U.S. Cl. CPC H01L 21/02068; C07F 7/10; C23G 5/00; H01L 21/02321

(57) ABSTRACT

A method for repairing copper and low-k dielectric films on a substrate is provided. In some embodiments, the method includes positioning the substrate within a process chamber, introducing a reducing agent into the process chamber to remove copper oxide from a copper layer on the substrate, removing the reducing agent from the process chamber, and introducing a recovery precursor into the process chamber to decrease a k value of a low-k film on the substrate.

### RELATED APPLICATIONS

This application claims benefit of and priority to U.S. Provisional Application No. 63/552,472 filed Feb. 12, 2024 which is herein incorporated in its entirety by reference for all purposes.

### BACKGROUND

### Field

Embodiments described herein generally relate to processes for processing low-k dielectric films. More specifically, embodiments described herein relate to processes for repairing copper and low-k dielectric films.

### Description of the Related Art

The dielectric constant (k) of dielectric films in semiconductor fabrication is continually decreasing as device scaling continues. Minimizing integration damage on low dielectric constant (low-k) films is important to be able to continue decreasing feature sizes. However, as feature sizes shrink, improvement in the resistive capacitance and reliability of dielectric films becomes a serious challenge.

Porous low-k dielectric films suffer significant damages after going through back end of line (BEOL) integration due to the contamination in the exposed pores, which leads to larger resistive-capacitive (RC) delay. In order to maintain the integrity of the low-k dielectric films and to minimize the oxidization on the copper, a method of restoring the copper and the low-k film is needed.

### SUMMARY

Embodiments described herein generally relate to processes for processing low-k dielectric films. More specifically, embodiments described herein relate to processes for repairing copper and low-k dielectric films.

In one embodiment, a method for repairing copper and low-k dielectric films is provided. The method includes positioning a substrate within a process chamber, and introducing a reducing agent into the process chamber to remove copper oxide from a copper layer on the substrate. After the copper oxide is removed, the method further includes removing the reducing agent from the process chamber and introducing a recovery precursor into the process chamber to decrease a k-value of a low-k film on the substrate.

In another embodiment, a method for repairing copper and low-k dielectric films is provided. The method includes positioning a substrate within a process chamber and introducing a reducing agent into the process chamber to remove copper oxide from a copper layer on the substrate. In some embodiments, the reducing agent comprises ammonia (NH3), hydrogen (H2), carbon monoxide (CO), ethanol (C2H5OH), methane (CH4), or ethene (C2H4). The method also includes turning on a UV light source to expose the substrate to UV light. After the copper oxide is removed, the method further includes removing the reducing agent from the process chamber and introducing a recovery precursor into the process chamber to decrease a k-value of a low-k film on the substrate.

In a further embodiment, a non-transitory computer-readable medium is provided. The non-transitory computer-readable medium comprises instructions that, when executed by a processor, cause a computer system to perform the steps of: positioning a substrate within a process chamber, introducing a reducing agent into the process chamber to remove copper oxide from a copper layer on the substrate, removing the reducing agent from the process chamber, and introducing a recovery precursor into the process chamber to decrease a k value of a low-k film on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of a process chamber, according to one or more embodiments.

FIG. 2 is a schematic block diagram view of a method of substrate processing, according to one or more embodiments.

FIGS. 3A-3C are molecular views of a low-k film during a method, according to one or more embodiments.

FIGS. 4A-4D are partial schematic side cross-sectional views of a semiconductor device during a method, according to one or more embodiments.

### DETAILED DESCRIPTION

Embodiments described herein generally relate to processes for processing low-k dielectric films. More specifically, embodiments described herein relate to processes for repairing copper and low-k dielectric films.

During back end of line processing operations, processing steps may damage copper layers by oxidizing the copper. Additionally, the processing steps may cause damage to low-k dielectric films through carbon loss (causing higher k values) and introducing undesirable Si-OH bonds (making the low-k surface hydrophilic). Accordingly, the techniques for repairing copper and low-k dielectric films described herein reverse the copper oxidation, decrease the k dielectric constant on the low-k films, and increase the hydrophobicity of the low-k films.

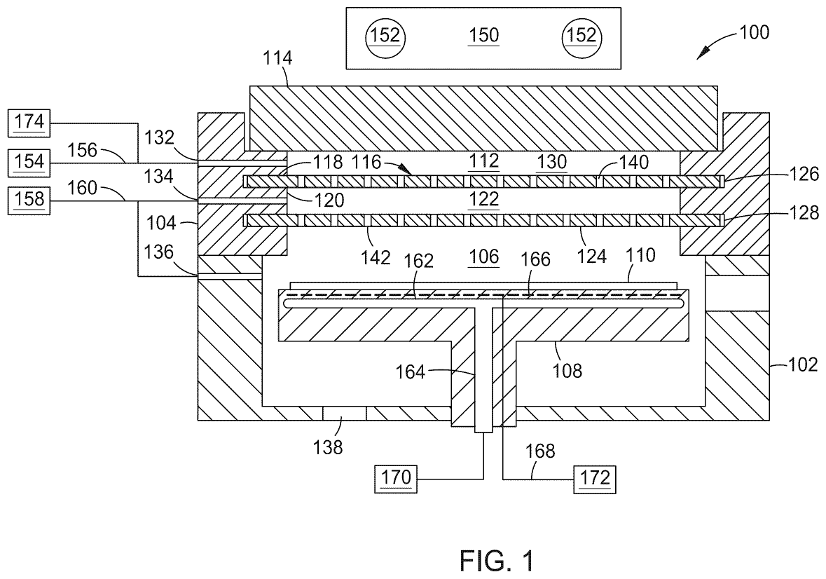

FIG. 1 is a schematic cross-sectional view of a process chamber 100, according to one or more embodiments. The process chamber 100 may be a vapor deposition chamber that includes UV radiation for assisting a silylation reaction. In one or more embodiments, the process chamber 100 may be the ONYX® or the SILENA® process chamber available from Applied Materials, Inc., of Santa Clara, California. The process chamber 100 may include a chamber body 102 and a chamber lid 104 disposed over the chamber body 102. The chamber body 102 and the chamber lid 104 may form an inner volume 106. A substrate support assembly 108 may be disposed in the inner volume 106. The substrate support assembly 108 may receive and support a substrate 110 thereon for processing.

A first UV transparent gas distribution showerhead 116 may be hung in the inner volume 106 through a central opening 112 of the chamber lid 104 by an upper clamping member 118 and a lower clamping member 120. The UV transparent glass distribution showerhead 116 may be positioned facing the substrate support assembly 108 to distribute one or more processing gases across a distribution volume 122 which is below the first UV transparent gas distribution showerhead 116. A second UV transparent showerhead 124 may be hung in the inner volume 106 through the central opening 112 of the chamber lid 104 below the first UV transparent gas distribution showerhead 116. Each of the UV transparent gas distribution showerheads 116, 124 may be disposed in a recess formed in the chamber lid 104. A first recess 126 may be an annular recess around an internal surface of the chamber lid 104, and the first UV transparent gas distribution showerhead 116 fits into the first recess 126. Likewise, a second recess 128 may receive the second UV transparent gas distribution showerhead 124.

A UV transparent window 114 may be disposed above the first UV transparent gas distribution showerhead 116. The UV transparent window 114 may be positioned above the first UV transparent gas distribution showerhead 116 forming a gas volume 130 between the UV transparent window 114 and the first UV transparent gas distribution showerhead 116. The UV transparent window 114 may be secured to the chamber lid 104 by any means, such as clamps, screws, bolts, etc.

The UV transparent window 114 and the first and second UV transparent gas distribution showerheads 116, 124 may be at least partially transparent to thermal or radiant energy within the UV wavelengths. The UV transparent window 114 may be quartz or another UV transparent material, such as sapphire, CaF₂, MgF₂, AlON, a silicon oxide material, a silicon oxynitride material, or another transparent material.

A UV source 150 may be disposed above the UV transparent window 114. The UV source 150 may be configured to generate UV energy and project the UV energy towards the substrate support assembly 108 through the UV transparent window 114, the first UV transparent gas distribution showerhead 116, and the second UV transparent gas distribution showerhead 124, thereby exposing the substrate 110 on the substrate support assembly 108 to UV light. A cover (not shown) may be disposed above the UV source 150. In one or more embodiments, the cover may be shaped to assist the projection of the UV energy from the UV source 150 towards the substrate support.

In one or more embodiment, the UV source 150 may include one or more UV lights 152 to generate UV radiation. The UV lights 152 may be lamps, LED emitters, or other UV emitters. In one or more embodiments, the UV lights 152 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, rare earth near-UV lamps such as europium-doped strontium borate or fluoroborate lamps discharging at 368-371 nm, to name a few examples.

The process chamber 100 may include flow channels 132, 134, 136 configured to supply one or more processing gases across the substrate support assembly 108 to process a substrate 110 disposed thereon. A first flow channel 132 provides a flow pathway for gas to enter the gas volume 130 and to be exposed to UV radiation from the UV source 150. The gas from the gas volume 130 may flow through the first UV transparent gas distribution showerhead 116 into the distribution volume 122. A second flow channel 134 may provide a flow pathway for precursor compounds and gases to enter the distribution volume 122 directly without passing through the first UV transparent gas distribution showerhead 116 to mix with the gas that was previously exposed to UV radiation in the gas volume 130. The mixed gases in the distribution volume 122 may be further exposed to UV radiation through the first UV transparent gas distribution showerhead 116 before flowing through the second UV transparent gas distribution showerhead 124 into a space proximate the substrate support assembly 108. The gas proximate the substrate support assembly 108, and a substrate disposed on the substrate support assembly 108, is further exposed to the UV radiation through the second UV transparent gas distribution showerhead 124. Purge gases may be provided through an opening 138 in the bottom of the process chamber 100 such that the purge gas flow around the substrate support assembly 108, preventing intrusion of processing gases into the space under the substrate support assembly 108. One or more gases may be exhausted through the opening 138.

The first UV transparent gas distribution showerhead 116 may include a plurality of holes 140 that allow processing gas to flow from the gas volume 130 to the distribution volume 122. The second UV transparent gas distribution showerhead 124 may also include a plurality of holes 142 that allow processing gas to flow from the distribution volume 122 into the processing space proximate the substrate support assembly 108. The holes 140, 142 in the first and second UV transparent gas distribution showerheads 116, 124 may be evenly distributed or irregularly spaced.

A purge gas or carrier gas source 154 may be coupled to the first flow channel 132 through a conduit 156. Purge gas from the purge gas source 154 may be provided through the first flow channel 132 during substrate processing to prevent intrusion of process gases into the gas volume 130. A cleaning gas source 174 may also be coupled to the first flow channel 132 through the conduit 156 to provide cleaning of the conduit 156, the first flow channel 132, the gas volume 130, and the rest of the chamber body 102 when not processing substrates.

A process gas or precursor compound source 158 may be coupled to the second flow channel 134 through a conduit 160 to provide a mixture, as described above, to the chamber body 102. The process gas source 158 may also be coupled to a third flow channel 136. Appropriate valves may allow selection of one or both of the flow channels 134, 136 for flowing the process gas mixture into the chamber body 202.

Substrate temperature may be controlled by providing heating and cooling features in the substrate support assembly 108. A coolant conduit 164 may be coupled to a coolant source 170 to provide a coolant to a cooling plenum 162 disposed in the substrate support assembly 108. One example of a coolant that may be used is a mixture of 50% ethylene glycol in water, by volume. The coolant flow is controlled to maintain temperature of the substrate at or below a desired level to promote deposition of UV-activated oligomers or fragments on the substrate. A heating element 166 may also be provided in the substrate support assembly 108. The heating element 166 may be a resistive heater, and may be coupled to a heating source 172, such as a power supply, by a conduit 168. The heating element 166 may be used to heat the substrate during the hardening process described above.

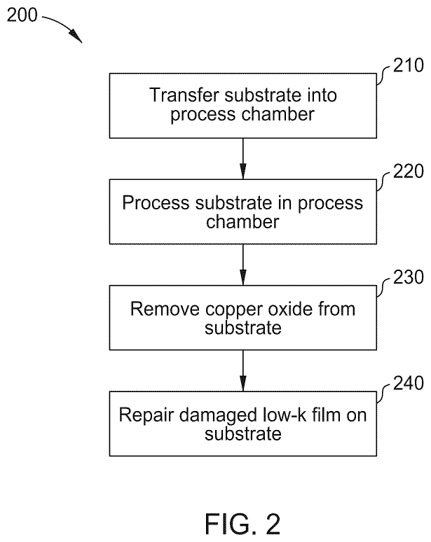

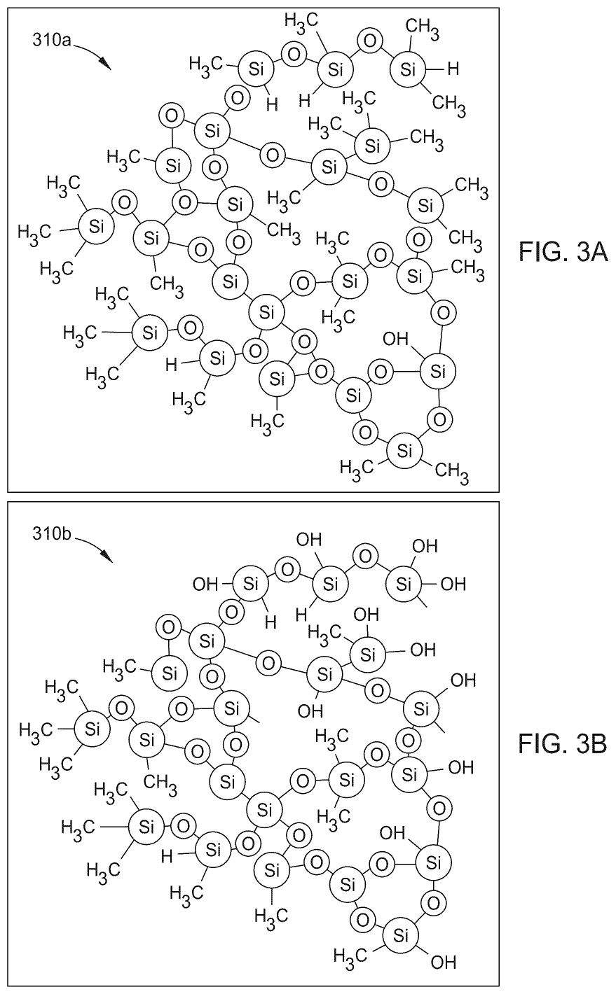

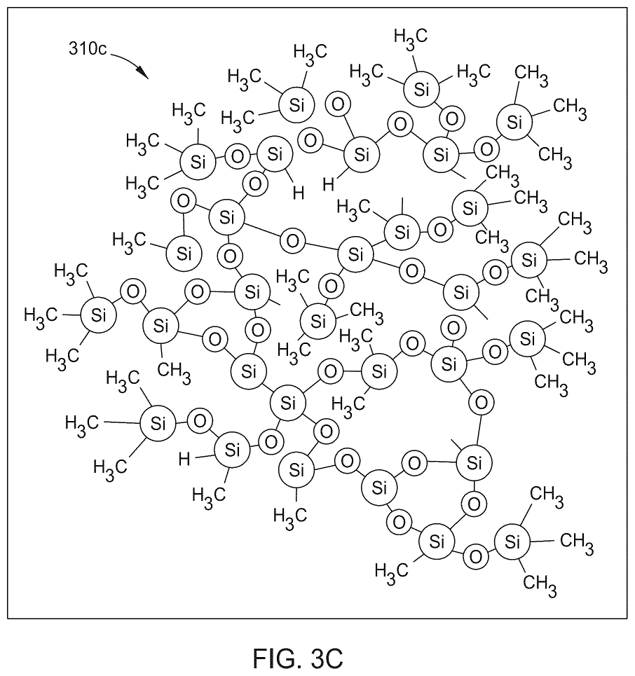

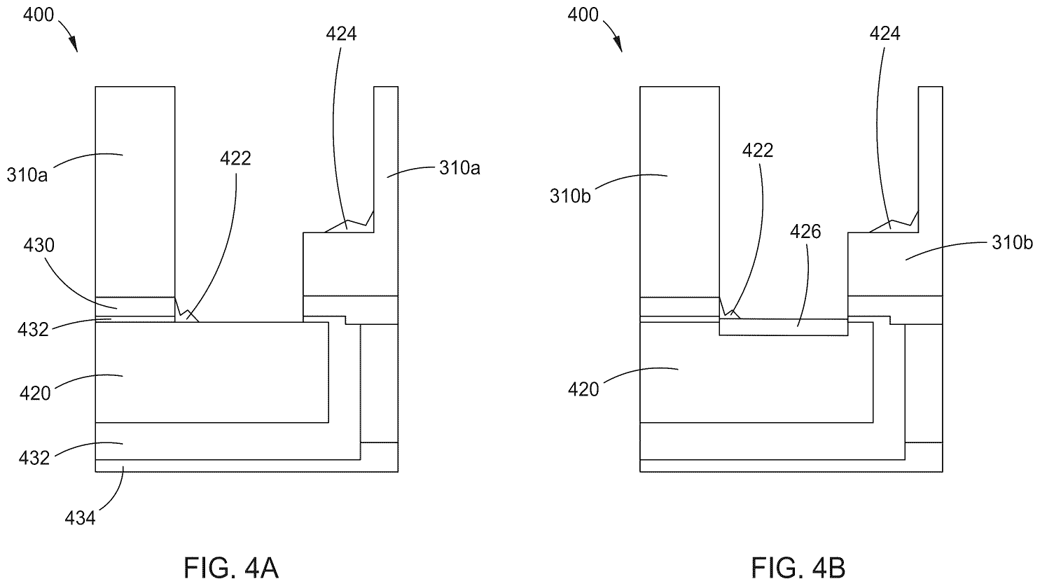

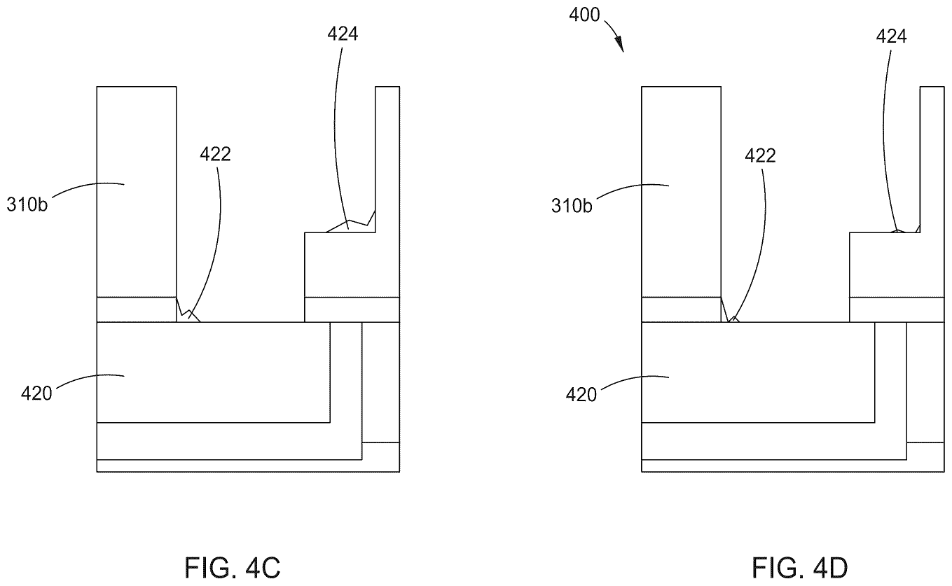

FIG. 2 is a schematic block diagram of a method 200 of substrate processing, according to one or more embodiments. FIGS. 3A-3C are molecular views of a low-k film 310a, 310b, 310c during the method 200, according to one or more embodiments. FIGS. 4A-4D are partial schematic side cross-sectional views of an interconnect structure 400 during the method 200, according to one or more embodiments.

At operation 210, a substrate, such as an interconnect structure 400 shown in FIG. 4A, is transferred into a process chamber. The process chamber may be a deposition process chamber such as the process chamber 100 depicted in FIG. 1. At operation 210, the interconnect structure 400 is post deposition, according to certain embodiments. The interconnect structure 400, shown in FIG. 4A may include a low-k film 310a on an etch stop layer 430, a metal barrier 432 between the etch stop layer 430 and a copper layer 420, a metal barrier 432 between the copper layer and a substrate 434, residue 422 on the copper layer 420, and residue 424 on the low-k film 310a. In some embodiments, an interconnect structure 400 with a different configuration may be utilized in method 200.

FIG. 3A is a molecular view of the low-k film 310a at operation 210. In FIG. 3A, the low-k film 310a has Si—O bonds, Si—CH₃ bonds, and Si—H bonds.

In some embodiments, the metal barrier 432 may comprise tantalum nitride (TaN).

At operation 220, the interconnect structure 400 is processed in the process chamber 100. As a result of operation 220, the copper layer 420 of the interconnect structure 400 is damaged. As shown in FIG. 4B, a copper oxide 426 may form on the copper layer 420, and the residue 422 on the copper oxide 426 may decrease. Operation 220 may also damage the low-k film 310b of the interconnect structure 400. As shown in FIG. 3B, the overall number of Si—CH₃ bonds in the low-k film 310b may be decreased, and Si—OH bonds may be formed. With the increase of Si—OH bonds, the low-k film 310b becomes more hydrophilic, which is undesirable. The decrease in Si—CH₃ bonds in the low-k film 310 results in an increased k value of the low-k film 310b. In some embodiments, the processing operations of operation 220 may include etching, ash, wet cleaning operations, or combinations thereof.

At operation 230, the copper oxide 426 on the interconnect structure 400 is removed from the copper layer 420, as shown in FIG. 4C. Operation 230 may be performed in the process chamber 100 utilizing a reducing agent and UV light. In some embodiments, the interconnect structure 400 may be exposed to UV light during operation 230. In some embodiments, the reducing agent may be a reducing gas such as ammonia (NH₃), hydrogen (H₂), carbon monoxide (CO), ethanol (C₂H₅OH), methane (CH₄), or ethene (C₂H₄). As shown in FIG. 4C, the low-k film 310b may remain damaged after operation 230.

In some embodiments, operation 230 may be performed at a temperature between about 75° C. and about 500° C. In some embodiments, operation 230 may be performed for a period ranging from about 1 minute to about 10 minutes. In some embodiments, operation 230 may be performed at a pressure between about 3 Torr and about 100 Torr. In some embodiments, operation 230 may be performed with a reducing gas flow ranging from about 100 sccm to about 2000 sccm. In some embodiments, operation 230 may be performed with RF power ranging from 0 W to about 1000 W. In some embodiments, operation 230 may be performed with a UV power percentage between 0% and about 90%.

After the completion of operation 230, the reducing gas may be removed from the process chamber.

TABLE 1

| Cu Reflectivity at 480 nm | | Process Parameters | | |
|---|---|---|---|---|
| After | After | NH₃ Pressure | NH₃ Flow | |
| Oxidation | UV/NH₃ | (Torr) | (sccm) | Cu Recovery |
| 0.122 | 0.630 | 20-50 | 500-2000 | 100% |
| 0.168 | 0.645 | 6.5-9.5 | 500-2000 | 100% |

In Table 1, the ability of UV and NH₃ to remove copper oxide 426 from the copper layer 420 is demonstrated. Copper reflectivity is utilized as an indication of the oxidation state of the copper layer 420. As shown in Table 1, the pressure of the NH₃ has little to no effect on the recovery of the copper layer 420. Additionally, by utilizing UV and NH₃ in operation 230, the copper layer 420 may be fully recovered.

At operation 240, as shown in FIG. 4D, the low-k film 310c is repaired. As shown in FIG. 3C, the low-k film 310c has fewer to no Si-OH bonds and a greater percentage of Si—CH₃ bonds than the low-k films 310a, 310b shown in FIG. 3A and FIG. 3B, respectively.

In some embodiments, operation 240 may be performed utilizing a recovery precursor. In some embodiments, operation 240 may also be performed utilizing UV light, for example, the interconnect structure 400 may be exposed to UV light during operation 240. In some embodiments, operation 240 may be performed via the chemical reactions (1) and (2) shown below. Chemical reactions (1) and (2) illustrate the removal of the Si—OH bonds and the formation of the Si—CH₃ bonds when the low-k film 310b is exposed to the recovery precursor

R₂N—Si—(CH₃)₃+HO—Si≡₍ₛ₎→(CH₃)₃—Si—O—Si≡₍ₛ₎+R₂NH_{(g)} (1)

HO—Si≡₍ₛ₎+HO—Si≡₍ₛ₎→≡Si—O—Si≡₍ₛ₎+H₂O_{(g)} (2)

The recovery precursor may include a molecule selected from Group 1. In Group 1, R may be independently selected from Me, Et, iPr, tBu, and H. R′ may be independently selected from an alkane, an alkene, and an alkyne. R′ may include between one and twenty carbon atoms.

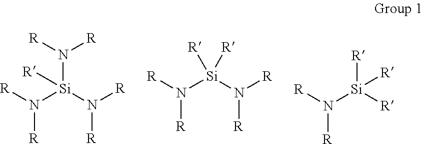

In one or more embodiments, the recovery precursor may be one of the molecules pictured in Group 1 Examples below.

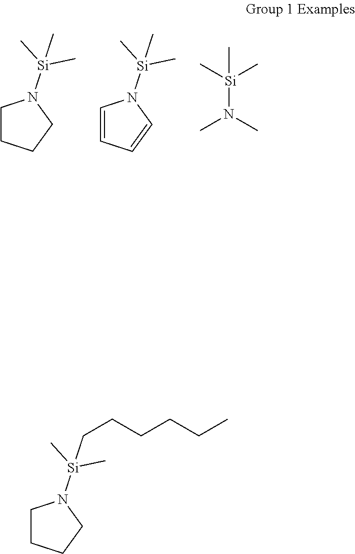

In certain embodiments, the recovery precursor may include a molecule selected from Group 2. In Group 2, R may be independently selected from Me, Et, iPr, and tBu. R′ may be independently selected from an alkane, an alkene, and an alkyne. R′ may include between one and twenty carbon atoms.

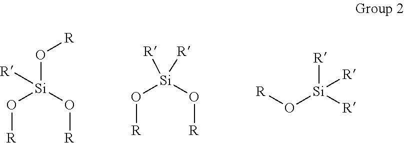

In certain embodiments, the recovery precursor may include a molecule selected from Group 3. In Group 3, X may be Cl, Br, or I. R′ may be independently selected from an alkane, an alkene, and an alkyne. R′ may include between one and twenty carbon atoms.

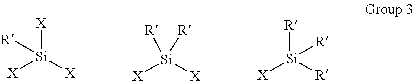

In certain embodiments, the recovery precursor may include a molecule selected from Group 4. In Group 4, R′ may be independently selected from an alkane, an alkene, and an alkyne. R′ may include between one and twenty carbon atoms.

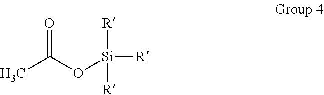

In certain embodiments, the recovery precursor may include a molecule selected from Group 5. In Group 5, R and R′ may be independently selected from hydrogen, an alkane, an alkene, an alkyne, and an aryl. In embodiments where R and/or R′ contain carbon, R and R′ may include between one and twenty carbon atoms each.

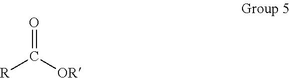

In certain embodiments, the recovery precursor may include a molecule selected from Group 6. In Group 6, R, R′, and R″ may be independently selected from hydrogen, an alkane, an alkene, an alkyne, and an aryl. In embodiments where R, R′, and/or R″ contain carbon, R, R′, and R″ may include between one and twenty carbon atoms each.

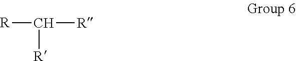

In some embodiments, operation 240 may be performed at a temperature between about 75° C. and about 500° C. In some embodiments, operation 240 may be performed for a period ranging from about 1 minute to about 10 minutes. In some embodiments, operation 240 may be performed at a pressure between about 3 Torr and about 100 Torr. In some embodiments, operation 240 may be performed with a gas flow of the recovery precursor ranging from about 100 mgm to about 2000 mgm.

It may be advantageous to perform operation 230 prior to operation 240 because recovery precursors are prone to be scavenged by copper oxide (CuOₓ), leading to Si residue on the copper layer 420, affecting via resistance.

The following non-limiting examples are provided to further illustrate embodiments described herein. However, the examples are not intended to be all inclusive and are not intended to limit the scope of the embodiments described herein.

TABLE 2

| | | First | 1^{st} | 2^{nd} | |
|---|---|---|---|---|---|
| Test | Substrate | Layer | Treatment | Treatment | Si |
| 1 | Si | Cu | Operation | None | 0.53 |
| | | | 230 + UV | | |
| 2 | Si | Cu | Operation | Operation 240 (no UV) | 1.90 |
| | | | 230 + UV | | |
| 3 | Si | Cu/CuO | None | Operation 240 (no UV) | 6.82 |
| 4 | Si | Cu/CuO | None | Operation 240 + UV 60s | 11.46 |
| 5 | Si | Cu | Operation | Operation 240 + UV 60s | 5.11 |
| | | | 230 + UV | | |

As shown in Table 2, copper oxide has an increased amount of silicon residue than reduced copper after operation 240. Additionally, performing operation 240 without UV may be desirable for minimizing the silicon residue on the copper surface.

TABLE 3

| | Water Contact Angle | |
|---|---|---|
| | (Center) (Degrees) | k |
| Low k film at Operation | 99.2 | 2.46 |
| 210 (FIG. 4A) | | |
| Post Operation 220 | <10 | 2.74 |
| Damage (FIG. 4B) | | |
| Post Operation 240 w/o | 89 | 2.61 |
| UV (FIG. 4D) | | |
| Post Operation 240 with | 93.7 | 2.59 |
| UV 60s (FIG. 4D) | | |
| Post Operation 240 | 79.3 | 2.60 |
| followed by UV 60s after | | |
| operation 240 (FIG. 4D) | | |

As shown in Table 3, the low-k film 310a had a high water contact angle and thus was hydrophobic. After the operation 220 damage, the low-k film 310b had a low water contact angle and thus was hydrophilic. Then, after operation 240, the low-k film 310c had a higher water contact angle and was thus hydrophobic. Operation 220 increased the k value, but k value was then partially recovered by operation 240. In some embodiments, UV exposure may be performed during operation 240 or sequentially after the recovery precursor process in operation 240. When UV exposure was performed after operation 240, the low-k film 310b had a lower water contact angle as compared to operation 240 without UV or operation 240 simultaneously with UV.

While the foregoing is directed to embodiments of the present disclosure, other and further embodiments of the disclosure may be devised without departing from the basic scope thereof, and the scope thereof is determined by the claims that follow.

1. A method, comprising:
positioning a substrate within a process chamber;
introducing a reducing agent into the process chamber to remove copper oxide from a copper layer on the substrate;
removing the reducing agent from the process chamber; and
introducing a recovery precursor into the process chamber to decrease a k-value of a low-k film on the substrate.

2. The method of claim 1, further comprising:
exposing the substrate to UV light during at least a portion of a time when the reducing agent is within the process chamber.

3. The method of claim 2, wherein the reducing agent is ammonia.

4. The method of claim 1, further comprising:
exposing the substrate to UV light during at least a portion of a time when the recovery precursor is within the process chamber.

5. The method of claim 1, wherein the recovery precursor is introduced to the process chamber after the reducing agent is removed from the process chamber.

6. The method of claim 1, wherein the recovery precursor comprises a molecule selected from a group consisting of: 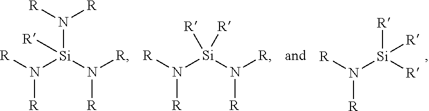
wherein R is independently selected from Me, Et, iPr, tBu, and H, and R′ is an alkane, alkene, or an alkyne.

7. The method of claim 1, wherein the recovery precursor comprises a molecule selected from a group consisting of

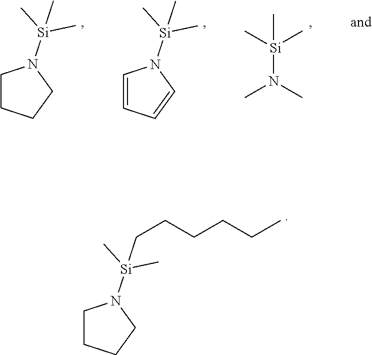

8. The method of claim 1, wherein the recovery precursor comprises a molecule selected from a group consisting of 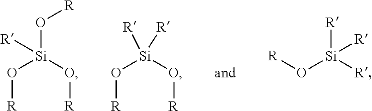
wherein R is independently selected from Me, Et, iPr, and tBu, and R′ is an alkane, alkene, or an alkyne.

9. The method of claim 1, wherein the recovery precursor comprises a molecule selected from a group consisting of 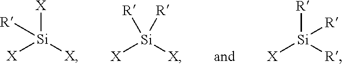
wherein X is Cl, Br, or I, and R′ is an alkane, alkene, or an alkyne.

10. The method of claim 1, wherein the recovery precursor comprises a molecule with a formula: 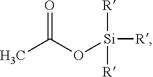
wherein R′ is an alkane, alkene, or an alkyne.

11. The method of claim 1, wherein the recovery precursor comprises a molecule with a formula: 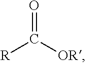
wherein R is hydrogen, an alkane, an alkene, an alkyne, or an aryl, and R′ is hydrogen, an alkane, an alkene, an alkyne, or an aryl.

12. The method of claim 1, wherein the recovery precursor comprises a molecule with a formula: 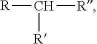
wherein R is hydrogen, an alkane, an alkene, an alkyne, or an aryl, R′ is hydrogen, an alkane, an alkene, an alkyne, or an aryl, and R″ is hydrogen, an alkane, an alkene, an alkyne, or an aryl.

13. The method of claim 1, wherein the reducing agent comprises ammonia (NH₃), hydrogen (H₂), carbon monoxide (CO), ethanol (C₂H₅OH), methane (CH₄), or ethene (C₂H₄).

14. A method, comprising:
positioning a substrate within a process chamber;
introducing a reducing agent into the process chamber to remove copper oxide from a copper layer on the substrate, wherein the reducing agent comprises ammonia (NH₃), hydrogen (H₂), carbon monoxide (CO), ethanol (C₂H₅OH), methane (CH₄), or ethene (C₂H₄);
turning on a UV light source to expose the substrate to UV light;
removing the reducing agent from the process chamber; and
introducing a recovery precursor into the process chamber to decrease a k value of a low-k film on the substrate.

15. The method of claim 14, further comprising:
turning off the UV light source prior to introducing the recovery precursor into the process chamber.

16. A non-transitory computer-readable medium storing instructions that, when executed by a processor, cause a computer system to perform the steps of:
positioning a substrate within a process chamber;
introducing a reducing agent into the process chamber to remove copper oxide from a copper layer on the substrate;
removing the reducing agent from the process chamber; and
introducing a recovery precursor into the process chamber to decrease a k value of a low-k film on the substrate.

17. The non-transitory computer-readable medium of claim 16, further comprising:
turning on a UV light source to expose the substrate to UV light.

18. The non-transitory computer-readable medium of claim 17, further comprising:
turning off the UV light source prior to introducing the recovery precursor into the process chamber.

19. The non-transitory computer-readable medium of claim 16, further comprising:
adjusting a flow rate of the recovery precursor to be between 100 mgm and 2000 mgm.

20. The non-transitory computer-readable medium of claim 16, further comprising:
adjusting a pressure inside the process chamber to be between 3 Torr and 100 Torr; and
adjusting a temperature inside the process chamber to be between 75° C. and 500° C.
